(19) United States
(12) Patent Application Publication
(10) Pub. No.: US 2019/0032193 A1
(43) Pub. Date: Jan. 31, 2019

(54) Vapor Deposition Device

(71) Applicant: WUHAN CHINA STAR OPTOELECTRONICS SEMICONDUCTOR DISPLAY TECHNOLOGY CO., LTD., Wuhan, Hubei (CN)

(72) Inventor: Junying Mu, Wuhan (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 15/575,877

(22) PCT Filed: Nov. 16, 2017
(86) PCT No.: PCT/CN2017/111251

§ 371 Date: Nov. 21, 2017

(30) Foreign Application Priority Data
Jul. 31, 2017 (CN) 201710639964.4

(51) Int. Cl. C23C 14/24; C23C 14/12; C23C 14/54

(52) U.S. Cl. CPC C23C 14/24; C23C 14/54; C23C 14/12

(57) ABSTRACT

A vapor deposition device includes an evaporation part, a nozzle, and an output part disposed between the evaporation part and the nozzle. The evaporation part is configured to evaporate vapor deposition material to form vapor. The nozzle is configured to transmit the vapor to the substrate. The output part is configured to transmit the vapor from the evaporation part to the nozzle. A surface of the output part facing the substrate is an arc surface.

### FIELD OF THE INVENTION

The present disclosure relates to the field of vapor deposition technologies, and more particularly to a vapor deposition device.

### BACKGROUND OF THE INVENTION

With development of organic light emitting diode (OLED) display technology, it has gradually become popular in the areas of mobile devices, wearable devices, large sized curved televisions, white light illumination devices, etc. OLED technology includes small molecule OLED technology and polymer OLED technology. An evaporation machine is a main equipment of small molecule OLED components. A core part of the evaporation machine is an evaporation source device.

The evaporation source device includes an integrated line evaporation source device and a conveying line evaporation source device. The conveying line evaporation source device includes an evaporation part, a transmission part, and an output part. The output part includes a plurality of evaporation nozzles. Material filled in the evaporation part is heated to form vapor. The vapor is transmitted to the output part through the transmission part, is outputted from the nozzle, and is deposited on a surface of a substrate. The existing evaporation source device has a large area facing the substrate and large heat radiation to the substrate, resulting in increased temperature or thermal deformation of the substrate and a fine metal mask (FMM) in a coating process.

### SUMMARY OF THE INVENTION

An object of the present disclosure is to provide a vapor deposition device capable of reducing thermal radiation to a substrate.

To achieve the above object, an embodiment of the present disclosure provides a vapor deposition device configured to form a vapor deposition film on a substrate, the vapor deposition device including:
an evaporation part configured to evaporate vapor deposition material to form vapor;
a nozzle configured to transmit the vapor to the substrate; and
an output part disposed between the evaporation part and the nozzle and configured to transmit the vapor from the evaporation part to the nozzle, wherein a surface of the output part facing the substrate is one of a concave arc surface and a convex arc surface.

In the vapor deposition device of an embodiment of the present disclosure, the nozzle includes a chamber, a heating part, an insulating part, and a cooling part, the chamber is configured to transmit the vapor, the heating part is disposed outside of the chamber and surrounds the chamber for heating the vapor, the insulating part is disposed outside of the heating part and surrounds the heating part for holding the vapor, and the cooling part is disposed outside of the insulating part and surrounds the insulating part for cooling the vapor.

In the vapor deposition device of an embodiment of the present disclosure, the nozzle further includes a temperature controller configured to increase an output power of the heating part to increase a temperature of the vapor when the temperature of the vapor is less than a preset temperature range, and the temperature controller is configured to reduce the output power of the heating part to reduce the temperature of the vapor when the temperature of the vapor is greater than the preset temperature range.

In the vapor deposition device of an embodiment of the present disclosure, the output part is a spherical shape.

In the vapor deposition device of an embodiment of the present disclosure, the vapor deposition device further includes a plurality of nozzles disposed on a surface of the output part facing the substrate.

In the vapor deposition device of an embodiment of the present disclosure, the vapor deposition device further includes a plurality of nozzles disposed on both sides of the output part.

In the vapor deposition device of an embodiment of the present disclosure, the vapor deposition device further includes a transmission part disposed between the evaporation part and the output part to transmit the vapor from the evaporation part to the output part.

In the vapor deposition device of an embodiment of the present disclosure, at least one of the evaporation part, the transmission part, and the output part includes a cooling structure, a heating structure, and a temperature monitor.

In the vapor deposition device of an embodiment of the present disclosure, the vapor deposition device further includes a rate monitor configured to monitor an evaporation rate of the evaporation part in real time.

An embodiment of the present disclosure further provides a vapor deposition device configured to form a vapor deposition film on a substrate, the vapor deposition device including:
an evaporation part configured to evaporate vapor deposition material to form vapor;
a nozzle configured to transmit the vapor to the substrate; and
an output part disposed between the evaporation part and the nozzle and configured to transmit the vapor from the evaporation part to the nozzle, wherein a surface of the output part facing the substrate is an arc surface.

In the vapor deposition device of an embodiment of the present disclosure, the nozzle includes a chamber, a heating part, an insulating part, and a cooling part, the chamber is configured to transmit the vapor, the heating part is disposed outside of the chamber and surrounds the chamber for heating the vapor, the insulating part is disposed outside of the heating part and surrounds the heating part for holding the vapor, and the cooling part is disposed outside of the insulating part and surrounds the insulating part for cooling the vapor.

In the vapor deposition device of an embodiment of the present disclosure, the nozzle further includes a temperature controller configured to increase an output power of the heating part to increase a temperature of the vapor when the temperature of the vapor is less than a preset temperature range, and the temperature controller is configured to reduce the output power of the heating part to reduce the temperature of the vapor when the temperature of the vapor is greater than the preset temperature range.

In the vapor deposition device of an embodiment of the present disclosure, the surface of the output part facing the substrate is a concave arc surface.

In the vapor deposition device of an embodiment of the present disclosure, the surface of the output part facing the substrate is a convex arc surface.

In the vapor deposition device of an embodiment of the present disclosure, the output part is a spherical shape.

In the vapor deposition device of an embodiment of the present disclosure, the vapor deposition device further includes a plurality of nozzles disposed on a surface of the output part facing the substrate.

In the vapor deposition device of an embodiment of the present disclosure, the vapor deposition device further includes a plurality of nozzles disposed on both sides of the output part.

In the vapor deposition device of an embodiment of the present disclosure, the vapor deposition device further includes a transmission part disposed between the evaporation part and the output part to transmit the vapor from the evaporation part to the output part.

In the vapor deposition device of an embodiment of the present disclosure, at least one of the evaporation part, the transmission part, and the output part includes a cooling structure, a heating structure, and a temperature monitor.

In the vapor deposition device of an embodiment of the present disclosure, the vapor deposition device further includes a rate monitor configured to monitor an evaporation rate of the evaporation part in real time.

Compared to the existing vapor deposition device, in the vapor deposition device of the embodiment of the present disclosure, a surface of the output part facing the substrate is an arc surface, such that a surface area facing the substrate and heat radiation of the vapor deposition device can be reduced, increased temperature or thermal deformation of the substrate and a fine metal mask (FMM) in a coating process can be improved. In addition, the heating part, the insulating part, and the cooling part are disposed in the nozzle to control a temperature of the vapor, and further, nozzles having different amounts, positions, apertures, and directions can be arranged to improve coating uniformity.

The technical solution of the present disclosure will be apparent from the following detailed description of embodiments of the present disclosure, with reference to the attached drawings.

### DESCRIPTION OF THE DRAWINGS

FIG. 1 is a schematic view illustrating a structure of a vapor deposition device according to an embodiment of the present disclosure.

FIG. 2 is a schematic cross-sectional view illustrating an evaporation part of a vapor deposition device according to an embodiment of the present disclosure.

FIG. 3 is a schematic view illustrating an output part of a vapor deposition device and a substrate according to an embodiment of the present disclosure.

FIG. 4 is a schematic cross-sectional view illustrating a nozzle of a vapor deposition device according to an embodiment of the present disclosure.

FIG. 5 is a schematic view illustrating a structure of another vapor deposition device according to an embodiment of the present disclosure.

### DETAILED DESCRIPTION OF THE PREFERRED EMBODIMENTS

The embodiments described herein with reference to the accompanying drawings are explanatory, illustrative, and used to generally understand the present disclosure. Furthermore, directional terms described by the present disclosure, such as top, bottom, front, rear, left, right, inner, outer, side, etc., are only directions by referring to the accompanying drawings, and thus the used terms are used only for the purpose of describing embodiments of the present disclosure and are not intended to be limiting of the present disclosure.

In the drawings, modules with similar structures are labeled with the same reference number.

Reference herein to “embodiment” means that a particular feature, structure, or characteristic described in connection with the embodiment can be included in at least one embodiment of the present disclosure. The appearances of the phrase in various places in the specification are not necessarily all referring to the same embodiment, nor are separate or alternative embodiments mutually exclusive of other embodiments. As such, the embodiments described herein, explicitly and implicitly understood by one skilled in the art, can be combined with other embodiments.

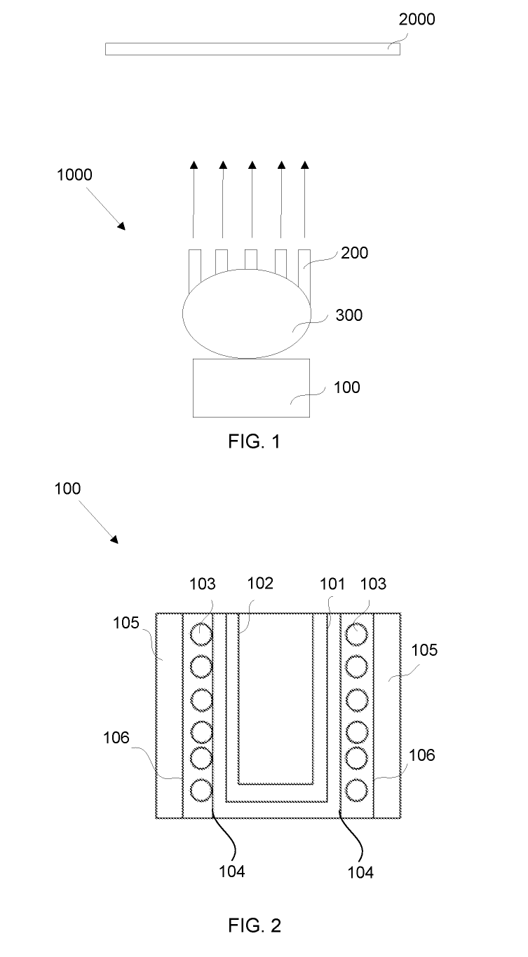

Refer to FIG. 1, a schematic view illustrating a structure of a vapor deposition device according to an embodiment of the present disclosure is provided. A vapor deposition device 1000 is configured to form a vapor deposition film on a substrate 2000. The vapor deposition device 1000 includes an evaporation part 100, a nozzle 200, and an output part 300 disposed between the evaporation part 100 and the nozzle 200.

The evaporation part 100 is configured to evaporate vapor deposition material to form vapor. The output part is configured to transmit the vapor from the evaporation part 100 to the nozzle 200. The nozzle is configured to transmit the vapor to the substrate 2000.

In some embodiments, referring to FIG. 2, the evaporation part 100 includes a first crucible 101, a second crucible 102, a heating structure 103, and a thermal insulating layer 104. The second crucible 102 includes a vapor deposition material, and the heating structure 103 may be a heating wire. In actual vapor deposition process, high-frequency alternating current passes through the heating structure 103 to generate a magnetic field, and the magnetic field passes through the thermal insulating layer 104 to generate an induced current and heat in the first crucible 101, to form vapor by heating the vapor deposition material in the second crucible 102.

In some embodiments, a cooling structure 105 and an insulating structure 106 may be disposed on the evaporation part 100. The cooling structure 105 is configured to reduce a temperature of heating vapor deposition material, and the insulating structure 106 is configured to maintain the current heating temperature. By controlling the heating structure 103, the temperature of the vapor deposition material can be precisely adjusted.

Further, a temperature monitor (not shown) may be disposed on the evaporation part 100 to monitor the temperature of heating vapor deposition material. The temperature of heating vapor deposition material is controlled by adjusting an output power of the heating structure 103, such that the vapor deposition material is uniformly sprayed onto the substrate 2000. In the embodiment, the temperature monitor may be implemented either in a hardware or in a software module.

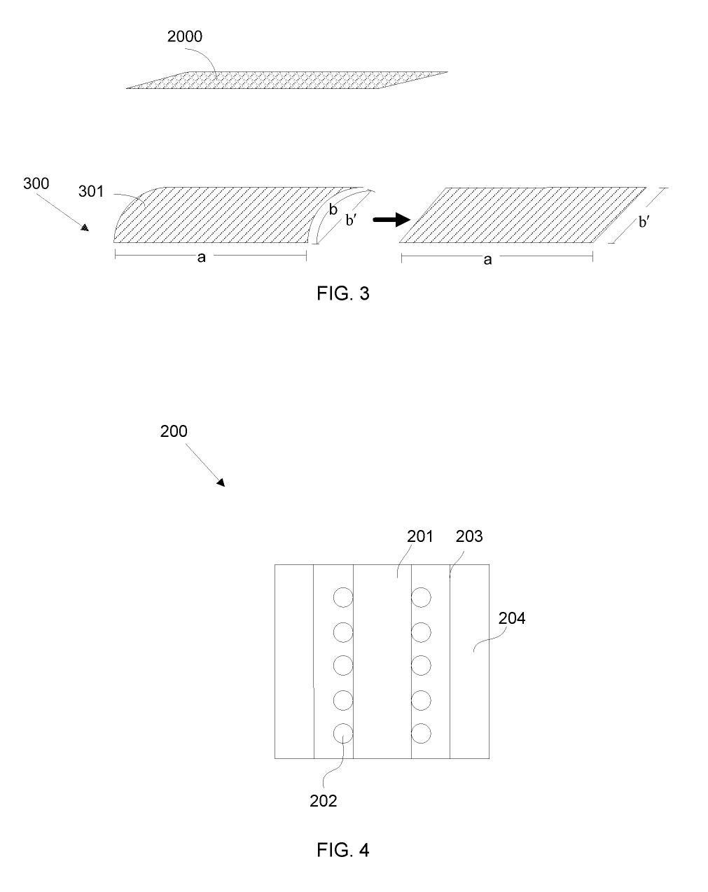

Refer to FIG. 1, a surface of the output part 300 facing the substrate 2000 is an arc surface. Refer to FIG. 3, a schematic view illustrating the output part 300 and the substrate 2000 is provided. The output part 300 shows only an arc surface 301 facing the substrate 2000. The arc surface 301 is a rectangular plane having a length a of 20 cm and a width b of 10 cm, and an intermediate position is formed upwardly. If a surface of the output part 300 facing the substrate 2000 is arranged to a horizontal shape, an area of the surface of the output part 300 facing the substrate 2000 is 20*10 cm². An area of the arc surface 301 facing the substrate 2000 is a*b′, where b′ is less than b, that is, the surface of the output part 300 facing the substrate 2000 is arranged to an arc surface. A surface area of the arc surface 301 facing the substrate 2000 is smaller, therefore, heat radiation of the output part 300 to the substrate 2000 can be reduced, thereby reducing thermal deformation of the substrate 2000 due to high temperature in a coating process. In some embodiments, a fine metal mask (FMM) is disposed on a side of the substrate 2000 facing the output part 300, and heat radiation from the output part 300 to the FMM can also be reduced.

In some embodiments, a surface of the output part 300 facing the substrate 2000 may be a convex arc surface, that is, an intermediate position is greater than a peripheral position. Refer to FIG. 1, the output part 300 may be a spherical shape. In some embodiments, a surface of the output part 300 facing the substrate 2000 may also be a concave arc surface, that is, an intermediate position is less than a peripheral position.

In some embodiments, a heating structure, a cooling structure, and a temperature monitor may be disposed on the output part 300 to further control a temperature of the vapor.

Refer to FIG. 4, a schematic cross-sectional view illustrating a nozzle of a vapor deposition device according to an embodiment of the present disclosure is provided. The nozzle 200 includes a chamber 201 configured to transmit the vapor. In order to further precisely control a temperature of the vapor, the nozzle 200 includes a heating part 202, an insulating part 203, and a cooling part 204. The heating part 202 is disposed outside of the chamber 201 and surrounds the chamber 201 for heating the vapor. The insulating part 203 is disposed outside of the heating part 202 and surrounds the heating part 202 for holding the vapor. The cooling part 204 is disposed outside of the insulating part 203 and surrounds the insulating part 203 for cooling the vapor. The heating part 202 includes a heating wire, the insulating part 203 includes a metal coating, and the cooling part 204 includes a refrigerant.

In some embodiments, the nozzle 200 further includes a temperature controller (not shown) configured to obtain a temperature of the vapor. The temperature controller is configured to increase an output power of the heating part to increase the temperature of the vapor when the temperature of the vapor is less than a preset temperature range, and the temperature controller is configured to reduce the output power of the heating part to reduce the temperature of the vapor when the temperature of the vapor is greater than the preset temperature range. The preset temperature range may be 100 to 120 degrees according to the actual situation, and is not particularly limited thereto. In detail, the temperature of the vapor can be detected by a temperature-measuring thermocouple disposed on the nozzle.

Refer to FIG. 3, a schematic view illustrating a structure of a liquid crystal display panel according to a second embodiment of the present disclosure is provided.

In some embodiments, the vapor deposition device 1000 includes a plurality of nozzles 200. In some embodiments, the nozzles 200 may be disposed on the arc surface of the output part 300 facing the substrate 2000, or may be disposed on both sides of the output part 300. In addition, the nozzles 200 may be uniformly disposed on the output part 300, or a larger number of the nozzles 200 may be disposed on both sides of the output part 300, and a smaller number of the nozzles 200 may be disposed on the arc surface 301 facing the substrate 2000. It is understood that the position and distribution of the nozzles 200 can be arranged according to actual needs, and the embodiment is not particularly limited.

In some embodiments, the nozzles 200 may be arranged in a same size and a same shape, such as a cylindrical shape, or a rectangular parallelepiped shape. For example, a diameter of the nozzle 200 having a cylindrical shape is 10 cm, such that the nozzles 200 disposed at different positions of the arc surface facing the substrate 2000 are not at a same level. A direction of a nozzle at a higher position may be changed to reduce a length of the linear vapor deposition device 1000, thereby avoiding excessive heat radiation from the vapor deposition device 1000 to the substrate 2000.

In some embodiments, different nozzles 200 may have different shapes and sizes. For example, the nozzle 200 disposed on the arc surface of the transmission part 300 is arranged in a cylindrical shape, and the nozzle 200 on both sides of the transmission part 300 is arranged in a cube shape. For example, a height of the nozzle 200 at a higher position of the arc surface is reduced, and a height of the nozzle 200 at a lower position of the arc surface is increased such that the nozzles 200 facing one side of the substrate 2000 have a same level along a same horizontal plane. It is understood that the shape and size of the nozzle 200 can be arranged according to actual needs, and the present embodiment is not particularly limited.

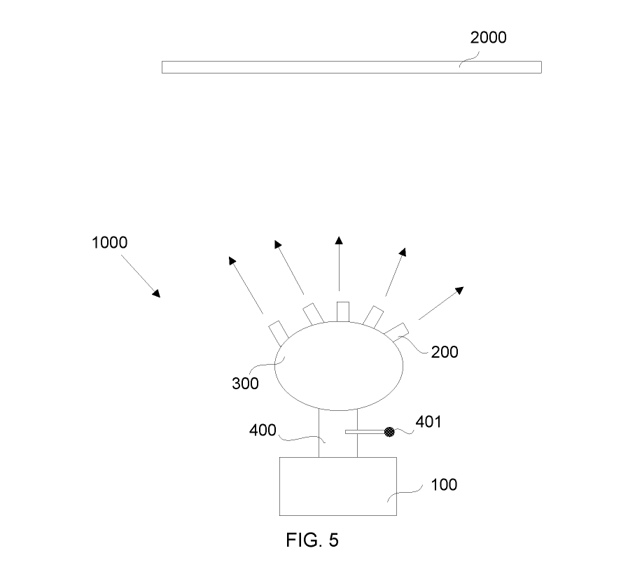

In some embodiments, referring to FIG. 5, the vapor deposition device 1000 further includes a transmission part 400 disposed between the evaporation part 100 and the output part 300 to transmit the vapor from the evaporation part 100 to the output part 300.

Similar to the output part 300, the heating structure, the cooling structure, and the temperature monitor may be disposed on the transmission part 400 to control the temperature of the vapor. The heating structure, the cooling structure, and the temperature monitor of the transmission part 400 are arranged in a manner similar to that of the evaporation part 100, and therefore, the embodiment will not be described again.

In some embodiments, the vapor deposition apparatus 1000 may further includes a rate monitor 401 to monitor an evaporation rate of the evaporation part 100. For example, the rate monitor 401 is disposed on the transmission part 400. The rate monitor 401 can be a valve. Speed of the vapor of the evaporation part 100 transmitted to the transmission part 400 is adjusted by adjusting an opening degree of the valve.

In the vapor deposition device 1000 of the embodiment of the present disclosure, a surface of the output part facing the substrate is an arc surface, such that a surface area facing the substrate and heat radiation of the vapor deposition device 1000 can be reduced, increased temperature or thermal deformation of the substrate in a coating process can be improved. In addition, the heating part, the insulating part, and the cooling part are disposed in the nozzle to control a temperature of the vapor, and further, nozzles having different amounts, positions, apertures, and directions can be arranged to improve coating uniformity.

The present disclosure has been described with a preferred embodiment thereof. The preferred embodiment is not intended to limit the present disclosure, and it is understood that many changes and modifications to the described embodiment can be carried out without departing from the scope and the spirit of the invention that is intended to be limited only by the appended claims.

What is claimed is:

1. A vapor deposition device configured to form a vapor deposition film on a substrate, comprising:
an evaporation part configured to evaporate vapor deposition material to form vapor;
a nozzle configured to transmit the vapor to the substrate; and
an output part disposed between the evaporation part and the nozzle and configured to transmit the vapor from the evaporation part to the nozzle, wherein a surface of the output part facing the substrate is one of a concave arc surface and a convex arc surface.

2. The vapor deposition device according to claim 1, wherein the nozzle comprises a chamber, a heating part, an insulating part, and a cooling part, the chamber is configured to transmit the vapor, the heating part is disposed outside of the chamber and surrounds the chamber for heating the vapor, the insulating part is disposed outside of the heating part and surrounds the heating part for holding the vapor, and the cooling part is disposed outside of the insulating part and surrounds the insulating part for cooling the vapor.

3. The vapor deposition device according to claim 2, wherein the nozzle further comprises a temperature controller configured to increase an output power of the heating part to increase a temperature of the vapor when the temperature of the vapor is less than a preset temperature range, and the temperature controller is configured to reduce the output power of the heating part to reduce the temperature of the vapor when the temperature of the vapor is greater than the preset temperature range.

4. The vapor deposition device according to claim 1, wherein the output part is a spherical shape.

5. The vapor deposition device according to claim 1, further comprising a plurality of nozzles disposed on a surface of the output part facing the substrate.

6. The vapor deposition device according to claim 1, further comprising a plurality of nozzles disposed on both sides of the output part.

7. The vapor deposition device according to claim 1, further comprising a transmission part disposed between the evaporation part and the output part to transmit the vapor from the evaporation part to the output part.

8. The vapor deposition device according to claim 7, wherein at least one of the evaporation part, the transmission part, and the output part comprises a cooling structure, a heating structure, and a temperature monitor.

9. The vapor deposition device according to claim 1, further comprising a rate monitor configured to monitor an evaporation rate of the evaporation part in real time.

10. A vapor deposition device configured to form a vapor deposition film on a substrate, comprising:
an evaporation part configured to evaporate vapor deposition material to form vapor;
a nozzle configured to transmit the vapor to the substrate; and
an output part disposed between the evaporation part and the nozzle and configured to transmit the vapor from the evaporation part to the nozzle, wherein a surface of the output part facing the substrate is an arc surface.

11. The vapor deposition device according to claim 10, wherein the nozzle comprises a chamber, a heating part, an insulating part, and a cooling part, the chamber is configured to transmit the vapor, the heating part is disposed outside of the chamber and surrounds the chamber for heating the vapor, the insulating part is disposed outside of the heating part and surrounds the heating part for holding the vapor, and the cooling part is disposed outside of the insulating part and surrounds the insulating part for cooling the vapor.

12. The vapor deposition device according to claim 11, wherein the nozzle further comprises a temperature controller configured to increase an output power of the heating part to increase a temperature of the vapor when the temperature of the vapor is less than a preset temperature range, and the temperature controller is configured to reduce the output power of the heating part to reduce the temperature of the vapor when the temperature of the vapor is greater than the preset temperature range.

13. The vapor deposition device according to claim 10, wherein the surface of the output part facing the substrate is a concave arc surface.

14. The vapor deposition device according to claim 10, wherein the surface of the output part facing the substrate is a convex arc surface.

15. The vapor deposition device according to claim 14, wherein the output part is a spherical shape.

16. The vapor deposition device according to claim 10, further comprising a plurality of nozzles disposed on a surface of the output part facing the substrate.

17. The vapor deposition device according to claim 10, further comprising a plurality of nozzles disposed on both sides of the output part.

18. The vapor deposition device according to claim 10, further comprising a transmission part disposed between the evaporation part and the output part to transmit the vapor from the evaporation part to the output part.

19. The vapor deposition device according to claim 18, wherein at least one of the evaporation part, the transmission part, and the output part comprises a cooling structure, a heating structure, and a temperature monitor.

20. The vapor deposition device according to claim 10, further comprising a rate monitor configured to monitor an evaporation rate of the evaporation part in real time.
